(19) United States
(12) Patent Application Publication
(10) Pub. No.: US 2011/0253860 A1
(43) Pub. Date: Oct. 20, 2011

(54) Apparatus and Method for Securing a Watthour Electrical Meter to a Socket Box

(75) Inventor: Zachary Leroy Davidson, Houston, TX (US)

(73) Assignee: DeWalch Technologies, Inc.

(21) Appl. No.: 13/033,544

(22) Filed: Feb. 23, 2011

Related U.S. Application Data
(63) Continuation of application No. 11/986,581, filed on Nov. 21, 2007, now abandoned.
Application No. 11/986,581 is a continuation-in-part of application No. 10/853,451, filed on May 25, 2004, now abandoned.

(51) Int. Cl. H05K 7/14; H05K 13/00

(52) U.S. Cl. 248/224.7; 29/592.1

(57) ABSTRACT

The instant disclosure relates to an apparatus and method for securing a watthour electrical meter to a socket meter box. A locking ring comprises a divided annular band fitted with tab members configured to accept a variety of ring fasteners. The tab members support a variety of ring fastener and fastener receiver assemblies, and have complementary mating surfaces that substantially mate around the head of an installed meter so that the locking ring is tamper-resistant. The ring fastener and fastener receiver have a number of complementary apertures disposed to receive either wire seals or other locking mechanisms.

### CROSS-REFERENCE TO RELATED APPLICATIONS

This application is a continuation of application Ser. No. 11/986,581, filed Nov. 21, 2007, which is a continuation-in-part of application Ser. No. 10/853,451, filed May 25, 2004.

The instant application claims priority to each of the above-referenced applications as noted above. All written material, figures, content and other disclosure in the above-referenced applications is hereby incorporated by reference.

### BACKGROUND OF THE INVENTION

Electrical service providers generally deliver electricity to their customers via power lines buried underground or distributed along poles or towers overhead. The provider's power lines are usually distributed from a power generation station to various sets of customer lines, so that customers can then use the power to satisfy their various electrical needs. To measure delivered power so that customers can be billed in proportion to their usage, service providers typically terminate their power lines at a customer's home or business facility through a metered socket box, various designs for which are well known.

For example, one known watthour meter socket consists of a meter box having two sets of electrical connections, with a provider's transmission lines being connected to one set of connections, and the customer's service lines to the other set. To establish a circuit and measure the amount of electricity a customer uses, the socket box is configured to accept a watthour meter, or another electricity usage measurement device, which, when plugged into the socket, permits transmission of electricity from the provider to the customer and allows the amount of transmitted electricity to be measured in watthours, so that the provider can charge the customer for power usage at an appropriate rate.

Various designs and uses for watthour meters are also well known, and all such designs and uses are incorporated into the teachings of the present invention. The present invention is also applicable in situations where the customer's electrical service lines are routed from the socket box to a breaker box, so that electricity can be distributed to various other service locations using additional sets of power lines or wires.

There are several known types of socket meter boxes, each being distinguished by the method in which the meter is secured in place once it has been plugged into the socket. For example, there is a ringless type meter box, which typically includes a meter box, an installed meter, and a box cover. A flange is formed around a meter head passage space disposed in a central portion of the box cover. A complementary flange is disposed on the meter base, so that the complementary flange sections join together when the meter head passage space is placed over and around the meter head. The meter box cover is then secured using a security device, for example, a small latch assembly or the like, disposed on the box cover, which functions in structural cooperation with a complementary latch-receiving member disposed on the meter box, thereby ensuring that the meter cannot be easily removed without first removing the cover after installation is complete.

As seen in FIG. 1, a ringed socket meter box 5 is also known, which typically includes a box cover flange 10 formed around a meter head passage space 12 cut out of a central portion of box cover 20. Meters used in conjunction with a ringed type socket meter box 5 are designed to interface with box cover flange 10 by means of a complementary mounting flange 40 disposed on the meter base, forming a watthour meter and meter box cover flange combination. The meter flange is then secured to the box flange by means of an annular, lockable sealing ring 50. The ring sealed meter socket box is designed such that, once a meter is plugged into the socket and the box cover is installed over the meter head, the meter cannot easily be removed without first removing the sealing ring. The box cover secures the meter to the electrical socket so that completion of an electrical circuit is ensured and reliably prevents the meter from falling out of the socket.

The box cover also prevents unauthorized persons from tampering with an installed meter. For example, some customers have attempted to bypass the meter, so that unmeasured electricity could be used free of charge. Also, service providers are sometimes forced to disconnect service to customers, for example, due to non-payment of monthly bills. In this event, the box cover keeps a customer from entering the socket box and reconnecting electrical service. However, in instances where a small latch assembly on the box fails to provide sufficient security for the meter and socket box, a sturdier, more tamper resistant solution is required.

In FIG. 2, a known lockable sealing ring is depicted in which an annular locking band 60 is divided so as to form two terminus portions 61, 62. In practice, locking band 60 is wrapped around the meter and box cover flange combination after the meter has been installed into an electrical socket disposed in the meter box. A diameter measured between interior surfaces of the band will vary depending on whether terminus portions 61, 62 are loosely disposed or drawn together.

Once terminus portions 61, 62 have been drawn together, a locking mechanism 70 is attached so that terminus portions 61, 62 are securely held. A fastener 75 is aligned with a captured nut 80, and then rotatably threaded into a receiving portion of captured nut 80. Installation of fastener 75 is usually completed using a screwdriver or another hand tool. As fastener 75 is progressively threaded into captured nut 80, terminus portions 61 and 62 are drawn together until the band is tightly wrapped around a circumference of the meter and box flange combination, thereby securing the meter in place within the box.

There are other known sealing ring housing and fastener configurations. For example, a box-sealing ring is disclosed in U.S. Pat. No. 5,851,038, in which a pair of sealing ring housings is disposed on opposite ends of an annular band. Bendable mounting tabs are extended from each of the ring housings into slots disposed in the band. A threaded fastener extends through a first threaded aperture disposed in one housing, and then through a second threaded aperture disposed in an opposite housing. An enlarged fastener head enables the installer to hand thread the fastener through each of the apertures during initial phases of installation. Fully threaded installation of the fastener is effected by inserting a screwdriver into receiving slots formed in each end of the fasteners and then rotating the screwdriver.

An axial slot cut in one end of the fastener is aligned with an aperture provided in the walls of the opposite housing member to permit attachment of a security device. Known methods of attaching the housings to the band include riveting the housings onto the ring, combining rivets with tabs to affix the housings to the band, and welding the housing to the ring.

In view of the foregoing, it is apparent there exists a strong need for an inexpensive and effective means by which a watthour meter can be reliably secured to a socket box cover. There is also a need for a meter box cover locking device that is simple in design, requires a reduced number of parts, and permits an installer to quickly, safely and effectively install the device in some cases without the use of tools.

### SUMMARY OF THE INVENTION

According to one example embodiment, an apparatus for securing a watthour meter to a meter box cover is provided comprising: an annular band, wherein a body portion of said annular band is divided to further comprise a first band portion and a second band portion; a first tab member disposed on said first band portion, wherein a first aperture region is formed through a body portion of said first tab member; a ring fastener having a first end and a second end; and a ring fastener support member for supporting disposition of said ring fastener through said first aperture region.

According to a further embodiment, a method of securing an electrical meter to a meter socket box is provided comprising: providing an annular band, wherein a body portion of said annular band is divided to further comprise a first band portion and a second band portion; disposing a first tab member on said first band portion, wherein a first aperture region is formed through a body portion of said first tab member; providing a ring fastener having a first end and a second end; and disposing a ring fastener support member in structural cooperation with said ring fastener to support disposition of said ring fastener through said first aperture region.

In another example embodiment of the apparatus, the ring fastener support member is adapted to selectively align the ring fastener with the ring fastener receiver.

Another example embodiment provides an apparatus for securing an electrical meter to a meter socket box, the apparatus including at least: an annular band, wherein a body portion of the annular band is divided to further comprise a first band portion and a second band portion; a first tab member formed from the first band portion, wherein a first aperture region is formed through a body portion of the first tab member; and a ring fastening member receiver disposed on the first tab member.

In another example embodiment of the apparatus, the apparatus further includes at least a ring fastening member, wherein the ring fastening member receiver is adapted to releaseably retain the ring fastening member.

In another example embodiment of the apparatus, the apparatus further includes at least a second tab member disposed on the second band portion, wherein a second aperture region is formed through a body portion of the second tab member.

In another example embodiment of the apparatus, the apparatus further includes at least a ring fastening member and a ring fastener support member for supporting disposition of the ring fastening member through the second aperture region.

These and other objects, features, and advantages herein will become apparent from the drawings, the descriptions given herein, and the appended claims. However, it will be understood that the above-listed objectives and/or advantages herein are intended only as an aid in quickly understanding aspects of example embodiments of the invention, are not intended to be limiting in any way, and therefore do not form a comprehensive or restrictive list of objectives, and/or features, and/or advantages.

The content and disclosure of the following applications are specifically hereby incorporated by reference: application Ser. No. 11/986,581, filed Nov. 21, 2007; and application Ser. No. 10/853,451, filed May 25, 2004.

There has thus been outlined, rather broadly, various features of example embodiments of the invention in order that the detailed description thereof may be better understood, and in order that the present contribution to the art may be better appreciated. There are additional features of example embodiments of invention that will be described hereinafter.

In this respect, before explaining at least one example embodiment of the invention in detail, it is to be understood that the example embodiments are not limited in their application to the details of construction and to the arrangements of the components set forth in the following description or illustrated in the drawings. Various example embodiments are capable of other further embodiments and of being practiced and carried out in various ways. Also, it is to be understood that the phraseology and terminology employed herein are for the purpose of the description and should not be regarded as limiting.

To the accomplishment of the above and related objects, example embodiments of the invention may be embodied in the form illustrated in the accompanying drawings, attention being called to the fact, however, that the drawings are illustrative only, and that changes may be made in the specific construction illustrated.

### BRIEF DESCRIPTION OF THE DRAWINGS

Various other objects, features and attendant advantages of embodiments of the invention will become fully appreciated as the same becomes better understood when considered in conjunction with the accompanying drawings, and wherein:

FIG. 1 is an exploded view of a typical watthour meter socket box, including a watthour meter and a known locking ring.

FIG. 2 is a close up view of a locking ring fastening means according to a previously known example of a locking ring.

FIG. 3a is a plan view of a locking ring according to an example embodiment of the invention.

FIG. 3b is a rotational view of the locking ring shown in FIG. 3a, in which two apertures are formed through body portions of opposed locking ring tab members.

FIG. 3c is a rotational view of the locking ring shown in FIG. 3a, in which four apertures are formed in the tab members.

FIG. 4a is a plan view of a locking ring having a ring fastener and fastener receiver assembly according to an example embodiment of the invention.

FIG. 4b is a close up view of the ring fastener shown in FIG. 4a, in which the fastener is shown installed through an aperture formed in a body portion of a tab member.

FIG. 4c is a close up view of the fastener receiver shown in FIG. 4a, in which the fastener receiver is shown installed through an aperture formed in a body portion of a tab member.

FIG. 5a is a plan view of the locking ring shown in FIG. 4a, in which opposed tab members are shown drawn together by means of an installed ring fastener and fastener receiver assembly.

FIG. 5b is a close up view of the ring fastener and fastener receiver assembly shown in FIG. 5a, in which terminus edge portions of opposed tab members are tightly drawn so as to hinder unauthorized tampering with the ring fastener and fastener receiver assembly after installation is complete.

FIG. 6a is a plan view of a ring fastener according to one aspect of an example embodiment of the invention.

FIG. 6b is a rotational view of the ring fastener shown in FIG. 6a, in which the ring fastener is rotated ninety degrees relative to the position shown in FIG. 6a.

FIG. 6c is a plan view of a ring fastener according to a further aspect of an example embodiment of the invention.

FIG. 6d is a plan view of a ring fastener according to a still further aspect of an example embodiment of the invention.

FIG. 6e is a plan view of a means of retaining a ring fastener according to a further aspect of an example embodiment of the invention.

FIG. 7a is a plan view of a fastener receiver according to one aspect of an example embodiment of the invention.

FIG. 7b is a plan view of a fastener receiver according to a further aspect of an example embodiment of the invention.

FIG. 8a is a plan view of a ring fastener and forming tool according to one aspect of an example embodiment of the invention.

FIG. 8b is a close up view of the ring fastener and forming tool shown in FIG. 8a, in which the ring fastener is shown partially inserted into the forming tool.

FIG. 8c is a cross-sectional view of a partially assembled ring fastener and forming tool according to a further aspect of the invention.

FIG. 9a is a plan view of a fastener receiver after swaging.

FIG. 9b is a plan view of a swaging tool.

FIG. 9c shows a cross-sectional view of a fastener receiver and swaging tool combination according to a further aspect of the invention.

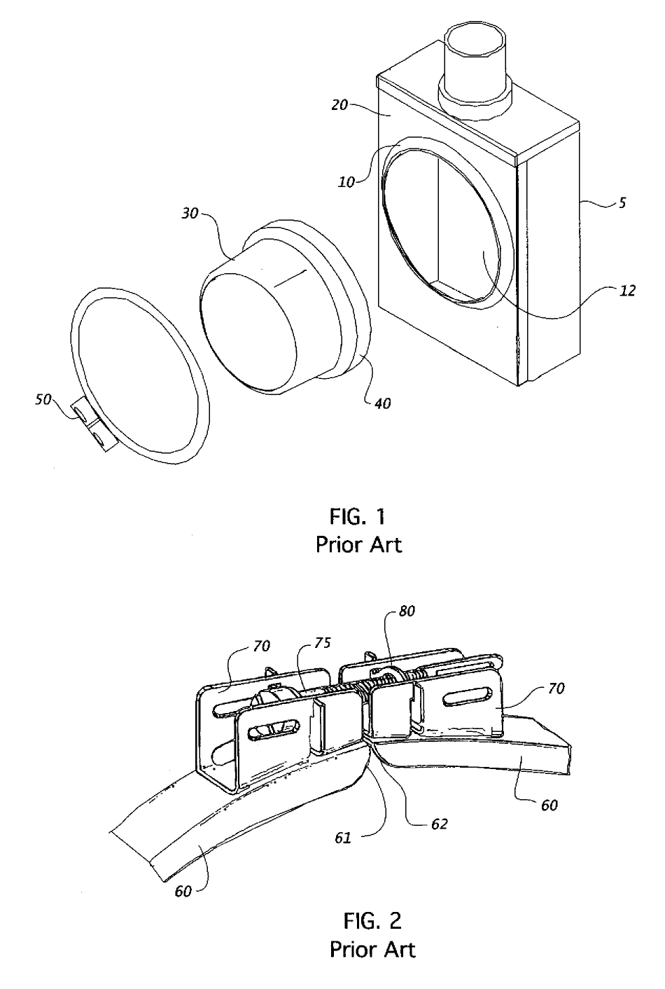

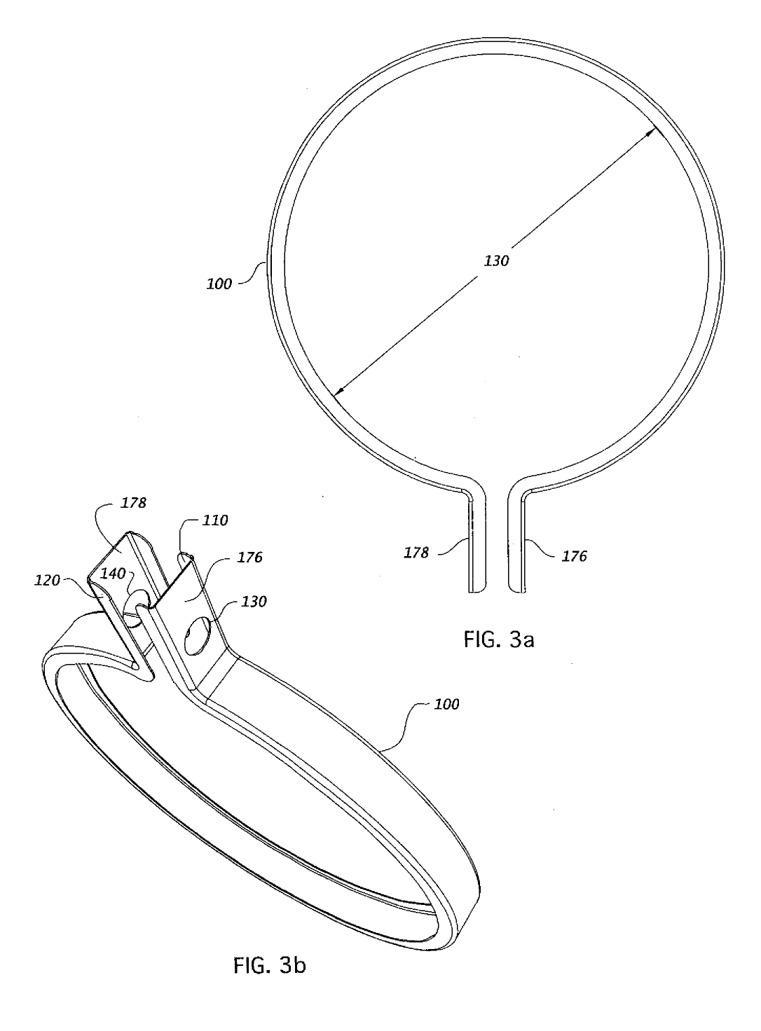

While various example embodiments of the invention will be described herein, it will be understood that it is not intended to limit the invention to those embodiments. On the contrary, it is intended to cover all alternatives, modifications, and equivalents included within the spirit of the invention.

### DETAILED DESCRIPTION OF THE INVENTION

Turning now to the drawings, the attached figures illustrate an apparatus for securing a plurality of structures. For example, in one embodiment, the apparatus is used for securing a watthour meter to a socket box. The apparatus may also be used for creating a tamper-evident seal or as a locking assembly with at least one structure as will hereinafter be explained in further detail.

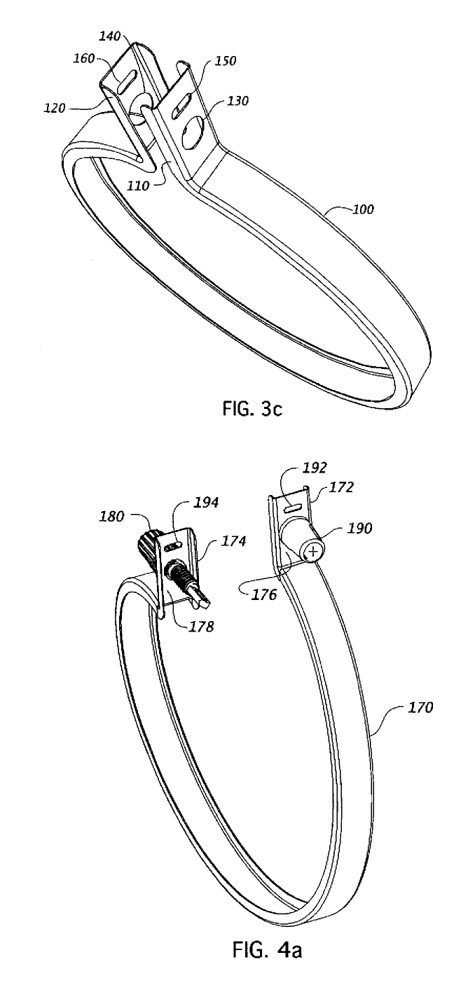

According to a specific, non-limiting embodiment of the invention, and referring now to FIG. 3a, an apparatus for securing a watthour electrical meter to a socket box cover comprises an annular band 100, a body portion of which is divided to comprise opposed tab members 176, 178. In certain embodiments, an interior diameter 130 of annular band 100 is selected to fit around a watthour meter and socket box flange combination in accord with industry standards, for example, in accord with the industrial standard for watthour meters set by the American National Standards Institute (“ANSI”). In other embodiments, however, an interior diameter 130 of annular band 100 is selected to secure electrical meters of non-standard or proprietary sizes that do not meet the ANSI industrial standards for watthour meters.

According to one example embodiment, annular band 100 is formed from a metallic material. In another embodiment, the band is extruded from a metal strip. In a further embodiment, the band material is rolled into the shape of an annular band. In a still further embodiment, the band is extruded from a solid rod. In other embodiments, annular band 100 is formed from a composite material, for example, from a hardened resin. In still other embodiments, annular band 100 is formed from plastic.

According to other aspects of the invention, apertures are formed in either one or both of the band's tab members to support installation of a ring fastening means. Forming apertures in the tab members is achieved in various embodiments by drilling, stamping, cutting or burning techniques, or using any other acceptable fabrication method available to one of ordinary skill in the art. In an alternative embodiment, only one ring tab member has an aperture portion formed therethrough, the other tab member comprising a complementary housing and nut assembly; in a further embodiment, the second tab member comprises a housing member for housing a rotatably secure fastener assembly.

Referring now to FIG. 3b, an isometric view of the apparatus for securing a watthour meter to a socket box shown in FIG. 3a is shown. Disposed through body portions of locking tab members 176, 178 are opposed, substantially circular apertures 130, 140; opposed tab member terminus portions 110, 120 are also provided. Each of apertures 110-140 support installation of numerous ring fastener and fastener receiver assemblies, as is discussed in greater detail below.

Tab members 176, 178 also perform multiple functions. For example, in some embodiments, tab members 176, 178 comprise support structures for fastener combinations used to draw terminus portions 110, 120 tightly together. In other embodiments, tab members 176, 178 are used as grasping points by installers during assembly, and permit terminus portions 110, 120 to be drawn tightly together so that a fastener and receiver combination can be engaged. Once tab member terminus portions 110, 120 are tightly drawn and tab members 176, 178 are locked together, any subsequent attempt to tamper with the installed ring fastener and receiver assembly is significantly hindered.

Referring now to FIG. 3c, an alternative embodiment is shown wherein a plurality of apertures 130-160 is formed in body portions of each of tab members 176, 178. In one example embodiment, apertures 130, 140 are substantially circular in shape, and permit a cylindrical ring fastener and fastener receiver combination to be attached. In another embodiment, apertures 150, 160 are substantially ovoid in shape, and are suitable for receiving any known fastening device that will fit within the confines of the apertures. It should be noted, however, that virtually any size or number of apertures of any shape can be employed, provided that reciprocal pairs of apertures are disposed on the tab members 176, 178 so that a fastening means can be reliably installed through each of the apertures prior to completion of installation.

In further embodiments, a wire seal is inserted through each of circular apertures 130, 140 in order to secure the tab members 176, 178 together. In still further embodiments, only apertures 150 and 160 are present, and a wire seal or a mechanical locking mechanism is used to hold the tab members together. In further embodiments still, tab members 176, 178 are secured by means of a mechanical lock, such as a padlock, a fastening end of which is inserted through each of two opposing apertures and then fastened into a body portion of the lock.

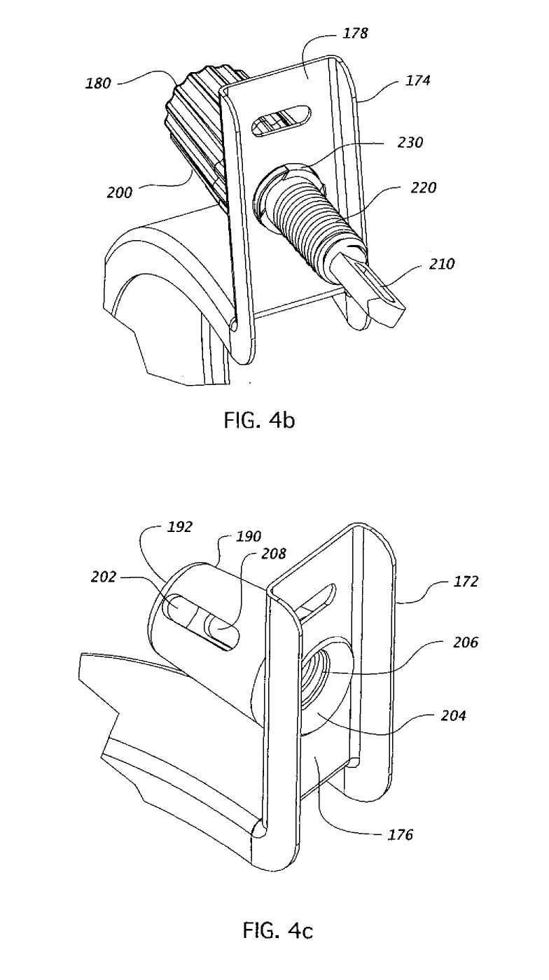

FIG. 4a illustrates an example embodiment of the invention where annular band 170 further comprises a pair of opposed tab members 176, 178, each having a circular aperture formed in a body portion through which ring fastener 180 and fastener receiver 190 have been installed. In some embodiments, ovoid apertures 192 and 194 are included so that a wire seal ring or a mechanical lock can also be attached.

In FIG. 4b, a close up view of ring fastener 180 is provided, wherein fastener 180 is installed through an aperture formed in a body portion of tab member 178. Ring fastener 180 has a gripping member 200 disposed at one end, and a threaded shaft 220 and ring fastener aperture 210 disposed at an opposite end. In certain embodiments, there is more than one ring fastener aperture 210 formed through ring fastener 180 at various axial locations around the ring fastener. In a presently preferred embodiment, a support shelf 230 rotatably supports ring fastener 180 after it has been passed through the aperture formed in tab member 178. In the embodiment depicted in FIG. 4b, gripping member 200 comprises a substantially cylindrical body, and includes a gripping surface that permits an installer to easily grasp and rotate the gripping member 200 during installation.

FIG. 4c is a close up view of fastener receiver 190 disposed in an aperture formed through a body portion of tab member 176. In some embodiments, a fastener aperture 192 is formed in a body portion of the fastener receiver 190. In other embodiments, fastener receiver 190 has a pair of opposed fastener apertures 202, 208 disposed at one end, and a threaded receiving portion 206 and a support member 204 combination disposed at an opposite end. Opposed apertures 202, 208 are disposed such that single a standard wire seal may be inserted through both apertures during installation. In other embodiments, a fastening member of a padlock or another mechanical lock is inserted through apertures 202, 208 and then secured by a locking mechanism disposed in a body portion of the lock.

In various other embodiments, apertures 202, 208 are disposed at other axial locations on the receiving member, and not necessarily the opposed axial locations shown in FIG. 4c. In further embodiments, there is only one aperture 202 formed through a body portion of fastener receiver 190. In still further embodiments, there are more than two apertures disposed formed through a body portion of fastener receiver 190, while in other embodiments, a plurality of opposed pairs of apertures is disposed at various other axial locations disposed around the body of fastener receiver 190.

Returning to FIG. 4a for a moment, a method of securing a watthour meter to a socket box is provided, wherein an installer grasps outer surfaces of tab members 176 and 178, and draws tab member terminus portions 172, 174 tightly together. After ring fastener 180 is aligned with an aperture formed through a body portion of tab member 178, a threaded shaft portion of ring fastener 180 is threaded through the aperture and into a threaded receiving portion of fastener receiver 190. After the ring fastener shaft is fully threaded into a body portion of fastener receiver 190, fastener 180 is finally tightened by means of a wheel knob rotated at the head of the fastener. In various other embodiments, an installer achieves final installation by tightening the ring fastener with a hand tool, such as a screwdriver or a ratchet.

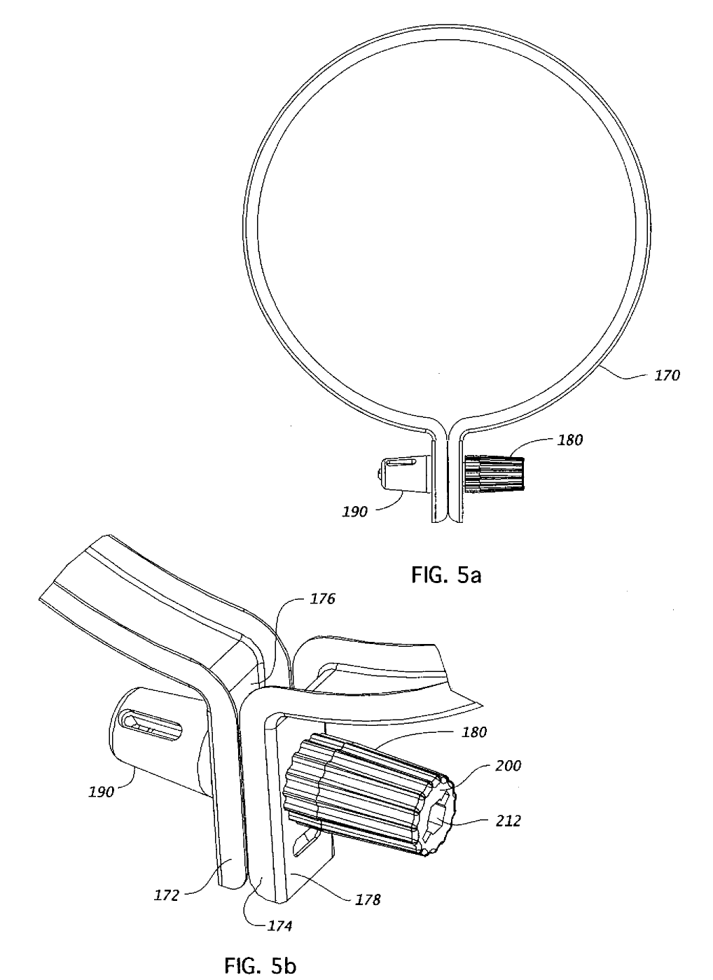

FIG. 5a is a plan view of the locking ring shown in FIG. 4a, in which opposed tab members are shown drawn together by means of an installed ring fastener 180 and fastener receiver 190 assembly. FIG. 5b is a close up view of the ring fastener 180 and fastener receiver 190 shown in FIG. 5a, in which terminus edge portions 172, 174 of opposed tab members 176, 178 are tightly drawn so as to hinder unauthorized tampering with the ring fastener 180 and fastener receiver 190 after installation is complete.

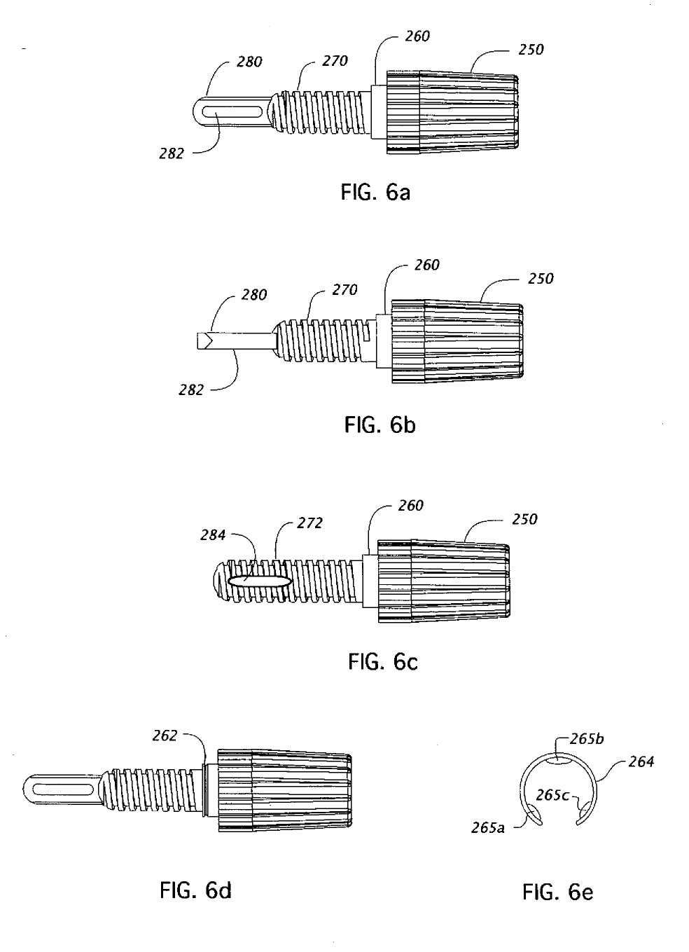

According to further aspects of the invention, and referring now to FIG. 6a, a ring fastener is provided comprising a gripping member 250, a support member 260, a threaded shaft 270, and a body portion 280 having a fastener aperture 282 formed therethrough. Gripping member 250 is used to thread and rotate the ring fastener during installation. Threaded shaft 270 is used to thread the fastener into a receiving member (not shown), and fastener aperture 282 is sized to accept a known metal sealing wire. In other embodiments, fastener aperture 282 is sized to receive a fastening portion of a padlock or other mechanical lock. FIG. 6b shows the ring fastener of FIG. 6a when rotated ninety degrees so that body portion 280 is viewed on edge.

In one embodiment, support member 260 has an outer circumference that is smaller than an inner circumference of the aperture through which it is to be installed; in this embodiment, the head of gripping member 250 is also larger than a circumference of the aperture. In various other embodiments, support shelf 260 has a circumference of about the same size as the circumference of gripping member 250.

In certain embodiments, the gripping member is formed structurally integral with a ring fastener shaft member. However, in alternative embodiments, the gripping member is formed separately from the ring fastener shaft member and then attached to the shaft member using known attachment methods, for example, by gluing or welding the gripping member to a head portion of the shaft member, or by threading a threaded portion of the shaft member head into a thread receiving portion cut into an interior portion of the gripping member.

FIGS. 6c-6e show various other embodiments of the ring fastener 250, in which various other apertures, threading and support member features are depicted. For example, in the embodiment depicted in FIG. 6c, ring fastener 250 further comprises a support shelf 260, and a fastener aperture 284 disposed within a threaded shaft portion 272 of ring fastener 250. In the example embodiment of FIG. 6d, a portion of the support shelf terminates in a recessed groove 262, around which a retaining member 264 (see FIG. 6e) is placed so that one or more tab members 265a-c fit down within the recessed groove to further inhibit removal of the ring fastener.

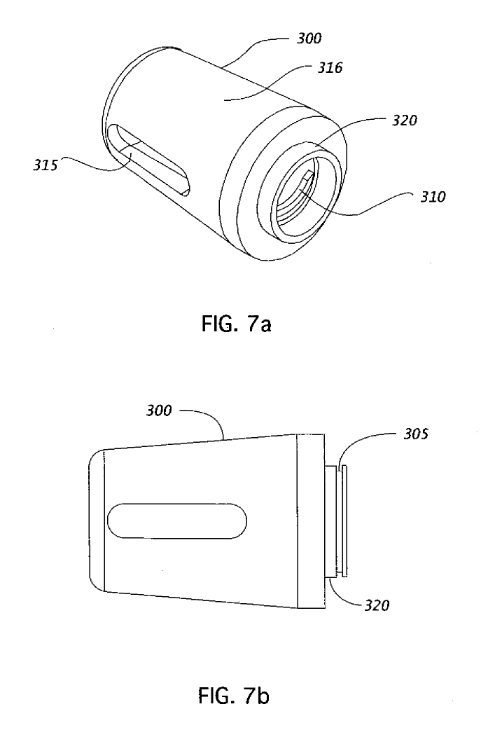

According to further aspects of the invention, and referring now to FIG. 7a, a fastener receiving 300 is shown having a threaded receiving portion 310. Threaded receiving portion 310 receives a ring fastener into a fastener receiver body portion 316. Threaded receiving portion 310 has an outer circumference smaller than the circumference of the aperture through which it will be installed. In some embodiments, a fastening aperture 315 is disposed in a body portion of fastener receiver 300; in other embodiments, fastening aperture 315 is sized so as to receive a padlock or other mechanical locking mechanism. According to certain embodiments, support member 320 is swaged into an aperture rather than threaded, using methods and means for swaging described in greater detail below. As seen in FIG. 7b, in certain embodiments support shelf 320 has a receiving channel 305 formed around an external circumference so as to receive a lock washer or the like.

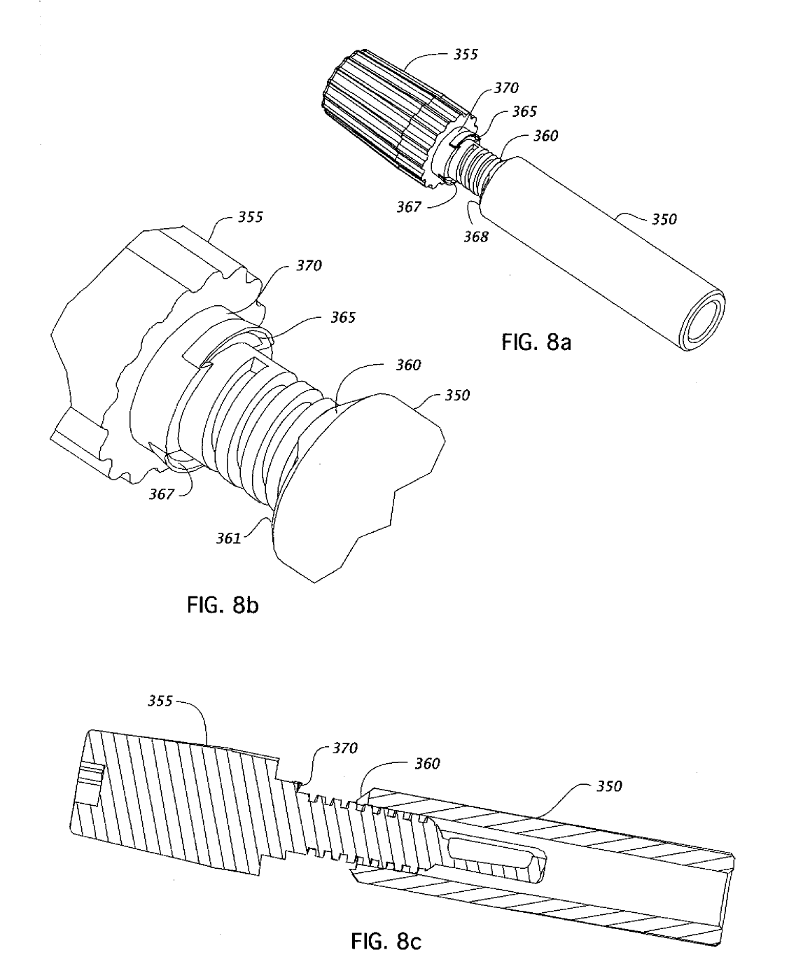

Turning now to FIG. 8a, a further aspect of the invention is shown comprising a ring fastener 355 and forming tool 350 combination. In one example embodiment, the forming tool is adapted to engage at least a portion of a ring fastener support member, such as for example, support member 260, as shown in FIG. 6a. In other example embodiments, the forming tool is essentially a staking tool 350 as shown in FIG. 8a. In the example embodiment depicted in FIG. 8a, forming tool 350 is a cylindrical housing, but in other embodiments it is contemplated that forming tool is conic or funnel shaped, and those of ordinary skill in the art will appreciate that other forming tool geometries, and combinations of forming tool geometries, will admit to satisfactory results according to the invention.

In one example method, forming tool 350 is employed by feeding a threaded shaft portion of ring fastener 355 through an interior cylindrical portion of forming tool 350, and then pressing staking protrusion 360 against support member 370 with sufficient force to dent or otherwise deform the support shelf 370. When staking protrusion 360 is pressed against support member 370 with sufficient force to increase the outer circumference of support member 370, ring fastener 355 cannot subsequently be easily removed from the assembly. Thus, after such an operation, the support member would be suitable for supporting, in one example embodiment, the ring fastener 355 though an aperture (e.g., 130, 140) of a given tab member (e.g., 176, 178).

According to one embodiment, the force required for staking protrusion 360 to deform support member 370 varies in proportion to the characteristics of the material from which ring fastener 355 is made. In one example embodiment, the amount of force required for staking protrusion 360 to deform support member 370 is between around 250 pounds and around 1,000 pounds per square inch. In other embodiments, however, satisfactory staking results are achieved by using less than around 250 pounds of force per square inch. In applications in which ring fastener 355 is formed from a less malleable material, a force greater than around 1,000 pounds per square inch is required for staking protrusion 360 to deform support member 370.

FIG. 8b is a close up view of ring fastener 355 and forming tool 350, shown after staking portion 360 has deformed portions 365, 367 of support member 370. Deformed portions 365, 367 are depicted in this embodiment as having been formed on opposite sides of support member 370; however, in alternative embodiments, only one deformed section 367 is formed on the support member 370 by applying force to staking protrusion 360. In various other embodiments, the entirety of support member 370 is deformed using staking portion 360.

FIG. 8c is a cross-sectional view of the embodiment shown in FIG. 8a, further comprising a forming tool 350 having a single staking protrusion 360. In other embodiments, multiple staking protrusions are disposed around a head portion of forming tool 350 so as to deform multiple sections of the support member 370 when sufficient force is applied to the staking protrusions. During a staking operation, ring fastener 355 is inserted into an aperture formed through a body portion of a tab member; a forming tool 350 is then fit over a threaded shaft portion of the ring fastener, and force is applied to the staking protrusion 360 (for example, by striking the fastener housing with a hammer or a mallet), until deformed regions develop around a circumference of support member 370.

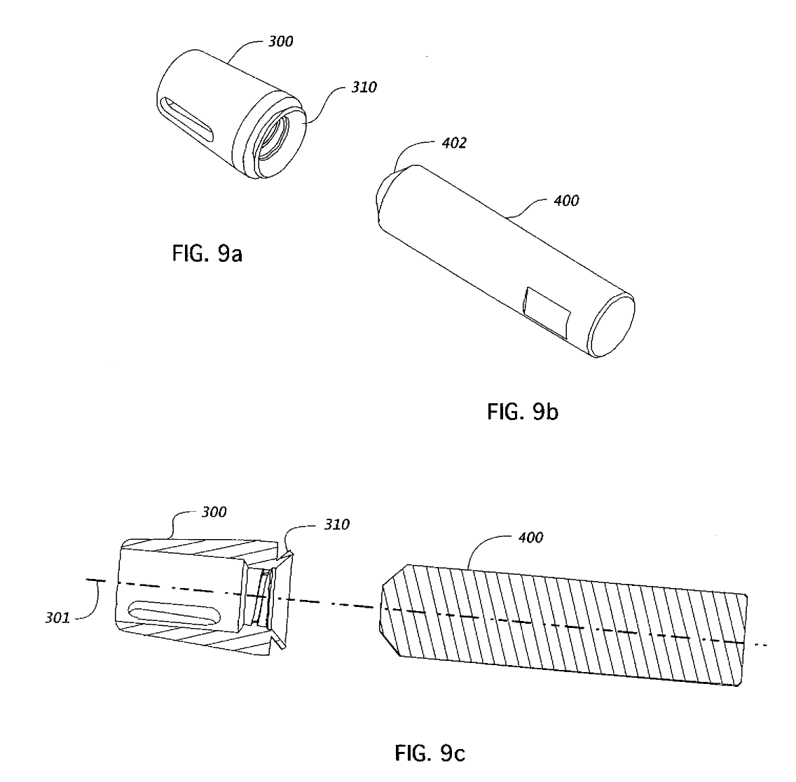

In another example embodiment, the forming tool is adapted to engage at least a portion of a ring fastener receiver, such as for example, fastener receiver 300 as shown in FIG. 7a. In other example embodiments, the forming tool 400 is essentially a swaging tool as shown in FIG. 9b. As seen in FIGS. 9a-9c, portions of a fastener receiver 300 may be deformed by means of, for example, a swaging tool (e.g., 400) or the like in order to make removal of the fastener receiver more difficult after installation is complete. For example, as seen in FIG. 9b, a swaging tool 400 comprises a body portion and a swaging portion 402. The swaging portion is forcefully applied to a receiving portion 310 disposed in fastener receiver 300 (see FIG. 9a) so as to deform a threaded region of receiving portion 310 and inhibit subsequent tampering.

It should be recognized that various other example embodiments may provide that at least a portion of the apparatus may be adapted for use on various utility service enclosures, transportation or cargo containers or on other enclosures needing a securing apparatus (for example, in various embodiments having tamper-evident seal features) or a locking apparatus. Moreover, a utility service enclosure or other containers, for example, may have various compatible configurations, shapes and sizes (e.g., with the apparatus or at least a fastening portion of the apparatus) and be used in the electric utility industry, (e.g., a meter box) as well as in the gas, water, cable, TV utility industries or in the shipping or transportation industries.

In another example embodiment, at least a fastening portion (e.g., a cylindrical ring fastener and fastener receiver combination; fastener and receiver housings, any of various barrel lock devices, threaded or unthreaded-type attaching or fastening devices and systems or other types of fastening assemblies or components) or any of various elements of the apparatus may be adapted to secure a plurality of structures (e.g., having any of various configurations and being used with enclosures, utility service enclosures (e.g., electrical, gas, water, etc.), shipping or transportation containers (e.g., for use in land, air or sea transport) or cargo vessel panels or doors, or other types of panels (e.g., flat, curved or other security panels or the like), structures, or containers needing to be secured) with each of the plurality of structures in some embodiments defining an aperture therein or some fastenable structural component or feature. As noted, the plurality of structures having apertures may be any of a variety of structures. In one example embodiment, the plurality of structures comprise first and second ends of any of various types of ring meter socket rings, which may be connected or disconnected, with the ring being adapted to mount a meter to a meter box structure. Each of the first and second ends of the ring, in one example embodiment, defines at least one aperture therein respectively for use with the at least a fastening portion.

In other example embodiments tamper-evident sealing features may be provided. A seal may comprise the at least a fastening portion of the apparatus, in some embodiments configured similarly to a locking pin (or, in other example embodiments, various types of barrel locks, or as noted earlier herein) which is adapted to unite a plurality of structures. One example of such structures would be the ends of a meter ring having apertures. However, the locking pin could also be configured to be used to unite a plurality of structures, used with a utility service enclosure, or for example used to lock (and/or seal or create a tamper-evident seal to indicate tampering with), for example, utility enclosures doors, lids or other secured panels, meter boxes, or trucking, shipping, airline or other transportation or cargo containers or other enclosures. The plurality of structures could include plate-like structures having apertures, engageable protrusions, or other engageable structural configurations such that the plate-like structures could be united with the at least a fastening portion of the apparatus to secure enclosures used in various industries.

The design described does not limit the scope of the embodiments of invention; the number of various elements may change, or various components may be added or removed to the above-described concept, for example, to aid in improved security and operation.

The foregoing disclosure and description of embodiments of the invention is illustrative and explanatory of the above and variations thereof, and it will be appreciated by those skilled in the art, that various changes in the design, organization, order of operation, means of operation, equipment structures and location, methodology, the use of mechanical equivalents, such as different types of fasteners and locking devices than as illustrated whereby different steps may be utilized, as well as in the details of the illustrated construction or combinations of features of the various elements may be made without departing from the spirit of the embodiments of the invention. As well, the drawings are intended to describe various concepts of embodiments of the invention so that presently preferred embodiments of the invention will be plainly disclosed to one of skill in the art but are not intended to be manufacturing level drawings or renditions of final products and may include simplified conceptual views as desired for easier and quicker understanding or explanation of embodiments of the invention. As well, the relative size and arrangement of the components may be varied from that shown and the embodiments of the invention still operate well within the spirit of the embodiments of the invention as described hereinbefore and in the appended claims. Thus, various changes and alternatives may be used that are contained within the spirit of the embodiments of the invention.

Accordingly, the foregoing specification is provided for illustrative purposes only, and is not intended to describe all possible aspects of the example embodiments of the invention. It will be appreciated by those skilled in the art, that various changes in the ordering of steps, ranges, interferences, spacings, hardware, and/or attributes and parameters, as well as in the details of the illustrations or combinations of features of the methods and system discussed herein, may be made without departing from the spirit of the embodiments of the invention. Moreover, while various embodiments of the invention have been shown and described in detail, those of ordinary skill in the art will appreciate that changes to the description, and various other modifications, omissions and additions may also be made without departing from either the spirit or scope thereof.

What is claimed is:

1. An apparatus for securing an electrical meter to a meter socket box, said apparatus comprising:
an annular band, wherein a body portion of said annular band is divided to further comprise a first band portion and a second band portion;
a first tab member formed from said first band portion, wherein a first aperture region is formed through a body portion of said first tab member;
a ring fastener having a first end and a second end; and
a ring fastener support member suitable for supporting disposition of said ring fastener through said first aperture region.

2. The apparatus for securing an electrical meter to a meter socket box of claim 1, further comprising a second tab member disposed on said second band portion.

3. The apparatus for securing an electrical meter to a meter socket box of claim 2, wherein said second tab member further comprises a second aperture formed through a body portion of said second tab member.

4. The apparatus for securing an electrical meter to a meter socket box of claim 1, wherein said ring fastener further comprises a threaded shaft disposed at said first end.

5. The apparatus for securing an electrical meter to a meter socket box of claim 4, further comprising a ring fastener receiver for receiving said threaded shaft of said ring fastener.

6. The apparatus for securing an electrical meter to a meter socket box of claim 1, wherein said ring fastener further comprises a fastening member disposed at said second end.

7. The apparatus for securing an electrical meter to a meter socket box of claim 1, wherein said ring fastener support member further comprises a support shelf.

8. The apparatus for securing an electrical meter to a meter socket box of claim 1, wherein at least a portion of said ring fastener support member is formed so as to rotatably support said ring fastener through said first aperture.

9. The apparatus for securing an electrical meter to a meter socket box of claim 1, further comprising a ring fastener receiver, wherein at least a portion of said ring fastener receiver is formed using a forming tool.

10. An apparatus for securing an electrical meter to a meter socket box, said apparatus comprising:
an annular band, wherein a body portion of said annular band is divided to further comprise a first band portion and a second band portion;
a first tab member formed from said first band portion, wherein a first aperture region is formed through a body portion of said first tab member;
a second tab member disposed on said second band portion, wherein a second aperture region is formed through a body portion of said second tab member;
a ring fastener having a first end and a second end, wherein said first end further comprises a threaded shaft and said second end further comprises a gripping member; and
a ring fastener support member for supporting disposition of said ring fastener through said first aperture region and said second aperture region.

11. A method of securing an electrical meter to a meter socket box, said method comprising:
providing an annular band, wherein a body portion of said annular band is divided to further comprise a first band portion and a second band portion;
forming a first tab member from said first band portion, wherein a first aperture region is formed through a body portion of said first tab member;
providing a ring fastener having a first end and a second end; and
disposing a ring fastener support member in structural cooperation with said ring fastener to support disposition of said ring fastener through said first aperture region.

12. The method of securing an electrical meter to a meter socket box of claim 11, further comprising disposing a second tab member on said second band portion.

13. The method of securing an electrical meter to a meter socket box of claim 12, wherein said disposing said second tab member further comprises disposing a second tab member further comprising a second aperture formed through a body portion of said second tab member.

14. The method of securing an electrical meter to a meter socket box of claim 11, wherein said disposing said ring fastener further comprises disposing a ring fastener comprising a threaded shaft disposed at said first end.

15. The method of securing an electrical meter to a meter socket box of claim 14, further comprising disposing a ring fastener receiver suitable for receiving said threaded shaft of said ring fastener.

16. The method of securing an electrical meter to a meter socket box of claim 11, wherein said disposing said ring fastener further comprises disposing a ring fastener comprising a fastening knob disposed at said second end.

17. The method of securing an electrical meter to a meter socket box of claim 11, wherein said disposing said ring fastener further comprises disposing a ring fastener comprising a support shelf.

18. The method of securing an electrical meter to a meter socket box of claim 11, wherein said disposing said ring fastener support member further comprises forming at least a portion of said ring fastener support member so as to rotatably support said ring fastener through said first aperture.

19. The method for securing an electrical meter to a meter socket box of claim 11, further comprising disposing a ring fastener receiver, wherein said disposing a ring fastener receiver further comprises forming at least a portion of said ring fastener receiver using a forming tool.

20. The method of securing an electrical meter to a meter socket box, said method comprising:
providing an annular band, wherein a body portion of said annular band is divided to further comprise a first band portion and a second band portion;
disposing a first tab member disposed on said first band portion, wherein a first aperture region is formed through a body portion of said first tab member;
disposing a second tab member disposed on said second band portion, wherein a second aperture region is formed through a body portion of said second tab member;
providing a ring fastener having a first end and a second end, wherein said first end further comprises a threaded shaft and said second end further comprises a fastening knob; and
disposing a ring fastener support member suitable for supporting disposition of said ring fastener through said first aperture region and said second aperture region.
